(19) United States
(12) Patent Application Publication
(10) Pub. No.: US 2023/0006012 A1
(43) Pub. Date: Jan. 5, 2023

(54) ORGANIC LIGHT EMITTING DISPLAY APPARATUS

(71) Applicant: LG Display Co., Ltd., Seoul (KR)

(72) Inventors: Youngnam LIM, Seoul (KR); Kwansoo KIM, Seoul (KR); Jae-Hyeon KIM, Paju-si (KR)

(73) Assignee: LG Display Co., Ltd., Seoul (KR)

(21) Appl. No.: 17/854,508

(22) Filed: Jun. 30, 2022

(30) Foreign Application Priority Data
Jun. 30, 2021 (KR) 10-2021-0085917

(51) Int. Cl. H01L 27/32; H01L 51/52

(52) U.S. Cl. CPC H01L 27/3246; H01L 51/5228; H01L 51/5209; H01L 27/3262; H01L 51/5237; H01L 27/3276

(57) ABSTRACT

An organic light emitting display apparatus according to an embodiment can include a display area configured to display images, a thin-film transistor disposed in the display area, at least one planarization layer disposed over the thin-film transistor and including at least one contact hole, a light emitting device disposed over the planarization layer and including a light emitting layer defining a first opening, a bank disposed in the first opening, a metal formation inhibiting layer disposed over the light emitting device and defining a second opening, and an auxiliary electrode disposed above the bank and in the second opening.

### CROSS-REFERENCE TO RELATED APPLICATION

This application claims priority to Korean Patent Application No. 10-2021-0085917 filed on Jun. 30, 2021, the entire contents of which are hereby expressly incorporated by reference into the present application.

### BACKGROUND

### Field

The present disclosure relates to an organic light emitting display apparatus having an organic light emitting device.

### Description of Related Art

An organic light emitting device used in an organic light emitting display apparatus is a self-light emitting device in which a light emitting layer is formed between two electrodes. Particularly, the organic light emitting device injects an electron and a hole respectively from an election injecting electrode (cathode) and a hole injecting electrode (anode) into the light emitting layer to emit light when an exciton formed as the electron and the hole are combined falls from an excited state to a ground state.

Generally, the organic light emitting display apparatus includes a display panel formed using such organic light emitting devices. The display panel can be implemented in a top-emission scheme, a bottom-emission scheme, a dual-emission scheme, and the like depending on a direction in which the light is emitted, and can be implemented in a passive matrix type, an active matrix type, and the like depending on a driving scheme. Further, the organic light emitting display apparatus can be implemented in various forms, such as to have a curved face by having ductility or to be artificially or mechanically bent.

The display panel of the organic light emitting display apparatus generally includes a plurality of sub-pixels arranged in a matrix form. Each sub-pixel disposed in the display panel of the organic light emitting display apparatus can include a transistor assembly and an organic light emitting diode.

The transistor assembly can include a switching transistor, a driving transistor, and a capacitor. The organic light emitting diode can include a lower electrode connected to the driving transistor included in transistor assembly, an organic light emitting layer, and an upper electrode.

The organic light emitting display apparatus can display a video as a selected sub-pixel emits light when a scan signal, a data signal, power, and the like are supplied to the plurality of sub-pixels arranged in the matrix form.

However, in a case of the organic light emitting display apparatus according to the related art, resistances of the electrodes formed in the panel can be relatively high. For this reason, there can be a problem of increased power consumption and non-uniformity in luminance in the organic light emitting display apparatus of the related art. As a result, there can be various difficulties and challenges, especially when implementing a large-area display apparatus.

### SUMMARY OF THE DISCLOSURE

The present disclosure is to realize a large-area organic light emitting display apparatus that can improve a display quality by reducing power consumption and ameliorating luminance non-uniformity.

Another object of the present disclosure is to provide an improved organic light emitting display apparatus which can address the limitations and disadvantages associated with the related art.

Purposes of the present disclosure are not limited to the above-mentioned purpose. Other purposes and advantages of the present disclosure that are not mentioned can be understood based on following descriptions, and can be more clearly understood based on embodiments of the present disclosure. Further, it will be easily understood that the purposes and advantages of the present disclosure can be realized using means shown in the claims and combinations thereof.

In order to achieve the purposes as described above, an organic light emitting display apparatus according to an embodiment of the present disclosure includes a substrate having a display area where a plurality of pixels are arranged and a non-display area around the display area. A thin-film transistor can be disposed on the display area of the substrate. A first electrode disposed over the thin-film transistor to be connected to a drain electrode of the thin-film transistor can be included. A bank disposed over the first electrode and having a first opening for exposing a portion of the first electrode can be included. A light emitting device can be disposed over the first electrode and in the first opening. A second electrode can be disposed over the light emitting device. A metal formation inhibiting layer disposed over the second electrode and having a second opening for exposing a portion of the second electrode at a location above the bank can be included. An auxiliary electrode positioned above the bank can be included. The auxiliary electrode can be electrically connected to the second electrode.

An organic light emitting display apparatus according to an embodiment can include a substrate having a display area and a non-display area adjacent to the display area where the display area includes a plurality of pixels, a thin-film transistor disposed in the display area of the substrate, a first electrode disposed over the thin-film transistor to be connected to a drain electrode of the thin-film transistor, a bank disposed over the first electrode and defining a first opening for exposing a portion of the first electrode, a light emitting stack disposed over the first electrode and in the first opening, a second electrode disposed over the light emitting stack, a metal formation inhibiting layer disposed over the second electrode and having a second opening for exposing a portion of the second electrode at a location above the bank, and an auxiliary electrode disposed above the bank, wherein the auxiliary electrode is electrically connected to the second electrode.

Further, an organic light emitting display apparatus according to an embodiment can include a display area configured to display images, a thin-film transistor disposed in the display area, at least one planarization layer disposed over the thin-film transistor and including at least one contact hole, a light emitting device disposed over the planarization layer and including a light emitting layer defining a first opening, a bank disposed in the first opening, a metal formation inhibiting layer disposed over the light emitting device and defining a second opening, and an auxiliary electrode disposed above the bank and in the second opening.

Other specific details of the embodiment are included in the detailed description and the drawings.

An organic light emitting display apparatus according to an embodiment of the present disclosure forms a metal formation inhibiting layer selectively patterned on top of a cathode electrode having a large resistance and an auxiliary electrode connected to a cathode electrode, so that an increase in a sheet resistance of the cathode electrode and a voltage drop of a power supply wiring can be minimized. Thus, a highly reliable display apparatus can be provided.

Effects of the present disclosure are not limited to the above-mentioned effects, and other effects as not mentioned will be clearly understood by those skilled in the art from following descriptions.

These and other objects of the present application will become more readily apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF DRAWINGS

The present disclosure will become more fully understood from the detailed description given hereinbelow and the accompanying drawings which are given by way of illustration only, and thus are not limitative of the present disclosure.

FIG. 1 is a schematic block diagram of an organic light emitting display apparatus according to one or more embodiments of the present disclosure.

FIG. 2 is a schematic circuit diagram of a sub-pixel usable in the organic light emitting display apparatus of FIG. 1.

FIG. 3 is an exemplary diagram schematically showing a circuit configuration of a sub-pixel usable in the organic light emitting display apparatus of FIG. 1 according to an embodiment of the present disclosure.

FIG. 4 is a schematic plan view of an organic light emitting display apparatus according to an embodiment of the present disclosure.

FIG. 5 is a schematic cross-sectional view of the organic light emitting display apparatus taken along line I-I′ in FIG. 4.

FIGS. 6 and 7 are views showing various shapes of an auxiliary electrode according to an embodiment of the present disclosure.

### DETAILED DESCRIPTION OF THE EMBODIMENTS

Advantages and features of the present disclosure, and a method of achieving the Advantages and features will become apparent with reference to embodiments described later in detail together with the accompanying drawings. However, the present disclosure is not limited to the embodiments as disclosed below, but can be implemented in various different forms. Thus, these embodiments are set forth only to make the present disclosure complete, and to completely inform the scope of the disclosure to those of ordinary skill in the technical field to which the present disclosure belongs, and the present disclosure is only defined by the scope of the claims.

A shape, a size, a ratio, an angle, a number, etc. disclosed in the drawings for describing the embodiments of the present disclosure are exemplary, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure can be practiced without these specific details. In other instances, well-known methods, procedures, components, and circuits have not been described in detail so as not to unnecessarily obscure aspects of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “including”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements can modify the entire list of elements and may not modify the individual elements of the list. In interpretation of numerical values, an error or tolerance therein can occur even when there is no explicit description thereof.

In addition, it will also be understood that when a first device or layer is referred to as being present “on” or “over” a second device or layer, the first device can be disposed directly on the second device or can be disposed indirectly on the second device with one or more third devices or layers being disposed between the first and second devices or layers. It will be understood that when an device or layer is referred to as being “connected to”, or “coupled to” another device or layer, it can be directly on, connected to, or coupled to the other device or layer, or one or more intervening devices or layers can be present. In addition, it will also be understood that when an device or layer is referred to as being “between” two devices or layers, it can be the only device or layer between the two devices or layers, or one or more intervening devices or layers can also be present between such devices/layers.

Further, as used herein, when a layer, film, region, plate, or the like is disposed “on” or “on a top” or “over” of another layer, film, region, plate, or the like, the former can directly contact the latter or still at least one other layer, film, region, plate, or the like can be disposed between the former and the latter. As used herein, when a layer, film, region, plate, or the like is directly disposed “on” or “on a top” or “over” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former can directly contact the latter or still at least one other layer, film, region, plate, or the like can be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event can occur therebetween unless “directly after”, “directly subsequent” or “directly before” is not indicated.

It will be understood that, although the terms “first”, “second”, “third”, and so on can be used herein to describe various elements, components, regions, layers and/or sections, these elements, components, regions, layers and/or sections should not be limited by these terms. These terms are used to distinguish one element, component, region, layer or section from another element, component, region, layer or section, and may not define order. Thus, a first element, component, region, layer or section described below could be termed a second element, component, region, layer or section, without departing from the spirit and scope of the present disclosure.

The features of the various embodiments of the present disclosure can be partially or entirely combined with each other, and can be technically associated with each other or operate with each other. The embodiments can be implemented independently of each other and can be implemented together in an association relationship.

As used herein, the term “substantially,” “about,” and similar terms are used as terms of approximation, and are intended to account for inherent deviations in measured or calculated values that would be recognized by those of ordinary skill in the art. The term can be used to prevent unauthorized exploitation by an unauthorized infringer to design around accurate or absolute figures provided to help understand the present disclosure.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the embodiments of the present disclosure will be described in detail with reference to the accompanying drawings. All components of each organic light emitting display apparatus according to all embodiments of the present disclosure are operatively coupled and configured.

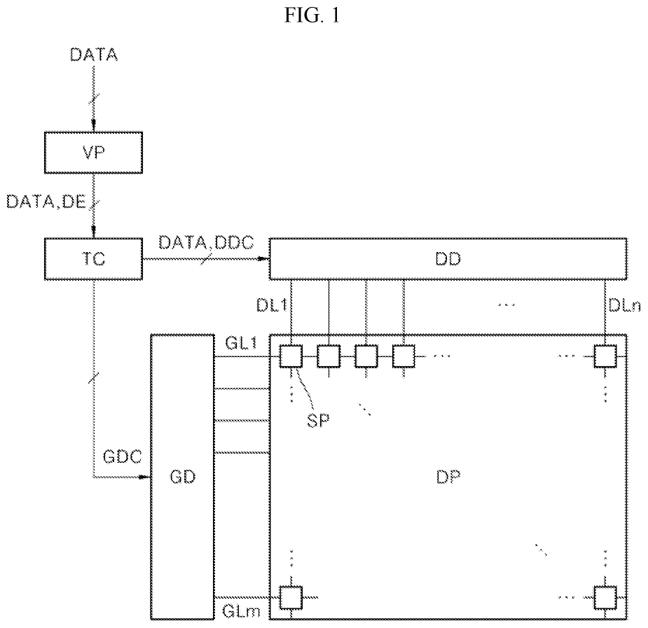

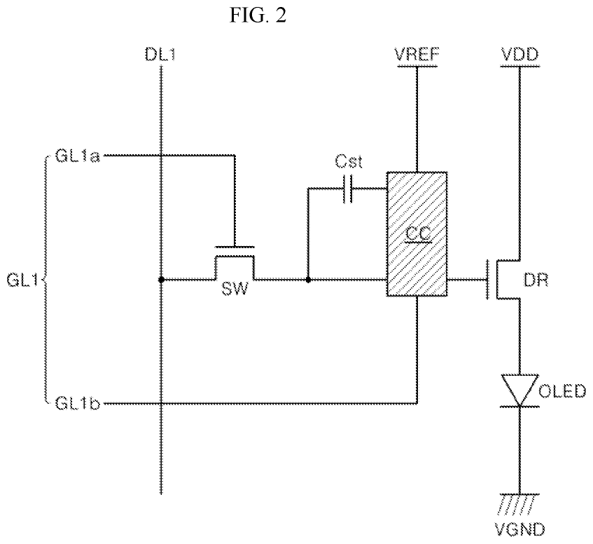

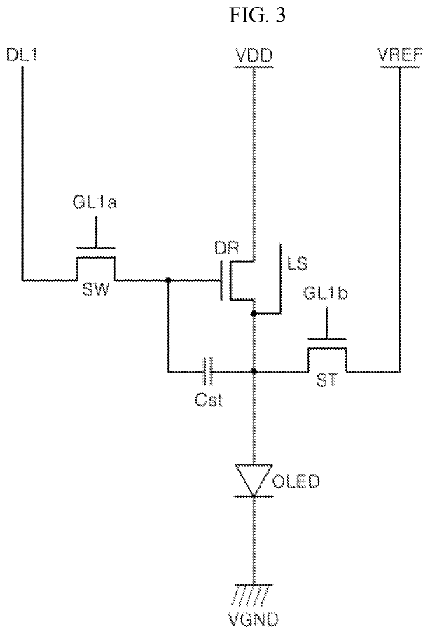

FIG. 1 is a schematic block diagram of an organic light emitting display apparatus, FIG. 2 is a schematic circuit diagram of a sub-pixel usable in the organic light emitting display apparatus of FIG. 1, and FIG. 3 is an exemplary diagram schematically showing a circuit configuration of a sub-pixel including a compensation circuit CC, which is usable in the organic light emitting display apparatus of FIG. 1 according to an embodiment of the present disclosure.

As shown in FIG. 1, the organic light emitting display apparatus includes a video processor VP, a timing controller TC, a data driver DD, a gate driver GD, and a display panel DP.

The video processor VP outputs a data enable signal DE and the like in addition to a data signal DATA supplied from the outside or an external device. The video processor VP can output at least one of a vertical synchronization signal, a horizontal synchronization signal, and a clock signal in addition to the data enable signal DE. The video processor VP can be formed in the form of an integrated circuit (IC) on a system circuit board, but can be of other types.

The timing controller TC (e.g., processor) receives the data signal DATA along with a driving signal including the data enable signal DE or the vertical synchronization signal, the horizontal synchronization signal, the clock signal, and the like from the video processor VP.

The timing controller TC outputs a gate timing control signal GDC for controlling the operation timing of the gate driver GD and a data timing control signal DDC for controlling the operation timing of the data driver DD based on the driving signal. The timing controller TC can be formed in the form of an IC on a control circuit board, but can be of other types. The timing controller TC also outputs the data signal DATA to the data driver DD.

The data driver DD samples and latches the data signal DATA supplied from the timing controller TC in response to the data timing control signal DDC supplied from the timing controller TC, and converts the data signal DATA into a gamma reference voltage and outputs the gamma reference voltage. The data driver DD outputs the data signal DATA via data lines DL1 to DLn, where n can be a positive number such as an integer greater than 1. The data driver DD can be formed in the form of the IC on a data circuit board, but can be of other types.

The gate driver GD outputs a gate signal in response to the gate timing control signal GDC supplied from the timing controller TC. The gate driver GD outputs the gate signal via gate lines GL1 to GLm, where m can be a positive number such as an integer greater than 1. The gate driver GD can be formed in the form of the IC on a gate circuit board or can be formed in a gate in panel scheme on the display panel DP or can be of other types.

The display panel DP displays a video/image in response to the data signal DATA and the gate signal respectively supplied from the data driver DD and the gate driver GD. The display panel DP includes a plurality of sub-pixels SP for displaying images such as videos, pictures, symbols, contents, etc.

Each sub-pixel SP can be formed in a top-emission scheme, a bottom-emission scheme, or a dual-emission scheme depending on a structure thereof. The sub-pixels SP can include a red sub-pixel, a green sub-pixel, and a blue sub-pixel, or can include a white sub-pixel, the red sub-pixel, the green sub-pixel, and the blue sub-pixel. The sub-pixels SP can have one or more different light emitting areas depending on light emitting characteristics. Other configurations are possible for the sub-pixels SP.

As shown in FIG. 2, each sub-pixel SP can include a switching transistor SW, a driving transistor DR, a capacitor Cst, a compensation circuit CC, and an organic light emitting diode OLED. The organic light emitting diode OLED operates to emit the light in response to a driving current formed by the driving transistor DR.

The switching transistor SW can perform a switching operation such that a data signal supplied via a first data line DL1 is stored as a data voltage in the capacitor Cst in response to a gate signal supplied via a first-a gate line GL1a. The driving transistor DR operates such that the driving current flows between a high potential power line VDD and a low potential power line VGND in response to the data voltage stored in the capacitor Cst.

The compensation circuit CC is a circuit for compensating a threshold voltage or the like of the driving transistor DR. The compensation circuit CC can be composed of at least one thin-film transistor and at least one capacitor. Various different configurations can be used for the compensation circuit CC and such configurations can be very diverse depending on a compensation method, so that one example of the configuration of the compensation circuit CC will be described as follows referring to FIG. 3.

As shown in FIG. 3, the compensation circuit CC can include a sensing transistor ST and a reference line VREF. The sensing transistor ST is connected to a portion (hereinafter, a sensing node) between a source line of the driving transistor DR and an anode electrode of the organic light emitting diode OLED. The sensing transistor ST operates to supply an initialization voltage (or a sensing voltage) transferred via the reference line VREF to the sensing node or to sense a voltage or a current of the sensing node.

In the switching transistor SW, a gate electrode is connected to the first-a gate line GL1a, a first electrode is connected to the first data line DL1, and a second electrode is connected to a gate electrode of the driving transistor DR.

In the driving transistor DR, the gate electrode is connected to the second electrode of the switching transistor SW, a first electrode is connected to the high potential power line VDD, and a second electrode is connected to the anode electrode of the organic light emitting diode OLED.

In the capacitor Cst, a first electrode is connected to the gate electrode of the driving transistor DR and a second electrode is connected to the anode electrode of the organic light emitting diode OLED. In the organic light emitting diode OLED, the anode electrode is connected to the second electrode of the driving transistor DR and a cathode electrode is connected to the low potential power line VGND.

In the sensing transistor ST, a gate electrode is connected to a first-b gate line GL1b, a first electrode is connected to the reference line VREF, and a second electrode is connected to the second electrode of the driving transistor DR and the anode electrode of the organic light emitting diode OLED, which is the sensing node.

In one example, an operating time of the sensing transistor ST can be similar to or the same as or different from that of the switching transistor SW depending on a compensation algorithm (or the configuration of the compensation circuit CC). The reference line VREF can be connected to the data driver DD. In this case, the data driver DD is able to sense the sensing node of the sub-pixel and generate a sensing result in real time, during a non-display period of the video, or for a period of N frames, where N is an integer equal to or higher than 1.

In addition, a compensation target based on the sensing result can be a data signal in a digital form, a data signal in an analog form, gamma signal, or the like. In addition, the compensation circuit CC for generating a compensation signal, a compensation voltage, or the like based on the sensing result can be implemented inside the data driver or inside the timing controller, or can be implemented as a separate circuit.

Further, a light blocking layer LS can be disposed only below a channel area of the driving transistor DR, or can be disposed not only below the channel area of the driving transistor DR but also below channel areas of the switching transistor SW and the sensing transistor ST. The light blocking layer LS can be used for a purpose of simply blocking external light, or the light blocking layer LS can be utilized as an electrode for connection with other electrodes or lines and for constituting the capacitor (e.g., Cst) or the like.

In addition, although FIG. 3 describes the sub-pixel of a 3T (transistor) 1C (capacitor) structure including the switching transistor SW, the driving transistor DR, the capacitor Cst, the organic light emitting diode OLED, and the sensing transistor ST as an example, the sub-pixel SP can have a structure of 3T2C, 4T2C, 5T1C, 6T2C, or the like when the compensation circuit CC is added.

Further, the thin-film transistors such as the switching transistor SW, the driving transistor DR, and the sensing transistor ST can be implemented based on low-temperature polysilicon (LTPS), amorphous silicon (a-Si), an oxide, or an organic semiconductor layer.

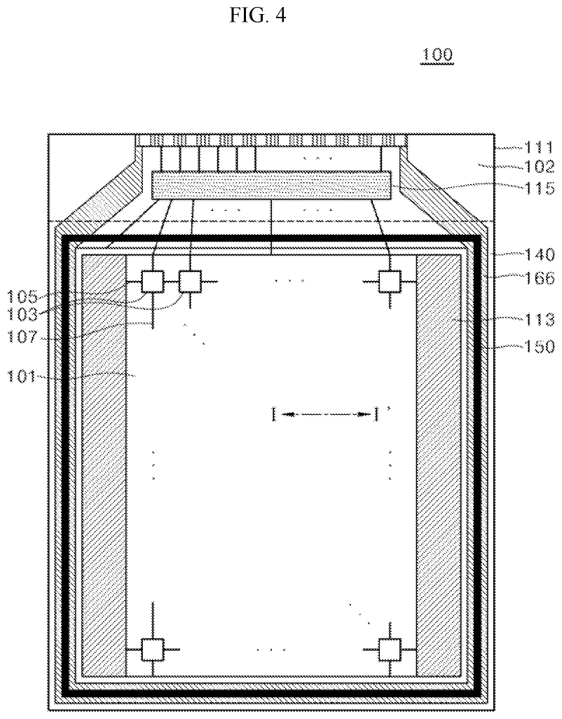

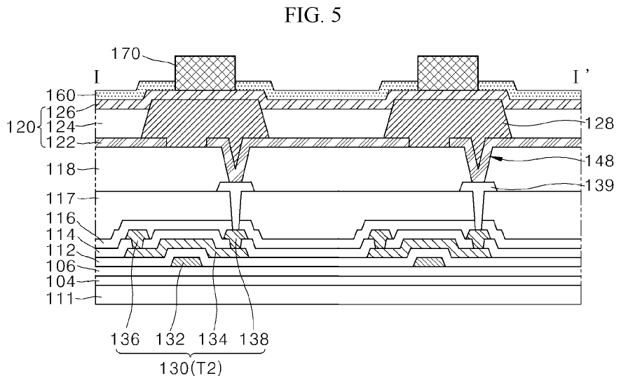

FIG. 4 is a schematic plan view of an organic light emitting display apparatus according to an embodiment of the present disclosure. FIG. 5 is a schematic cross-sectional view of the organic light emitting display apparatus taken along line I-I′ in FIG. 4.

Referring to FIG. 4, an organic light emitting display apparatus 100 includes a plurality of pixel 103 arranged on a substrate 111, a gate driver 113 configured to drive a plurality of gate lines 105, a data driver 115 configured to apply a video signal to a plurality of data lines 107, a common voltage line 166 formed outwardly of the gate driver 113 and supplying a common voltage Vss to the plurality of pixels 103, a voltage line 150 and an encapsulation portion 140. The voltage line 150 may supply a voltage to the plurality of pixels 103 together with the common voltage line 166.

The plurality of pixels 103 can be arranged in a matrix configuration, and can be at least composed of sub-pixels that can emit light of red, green, and blue (RGB) colors, but other color emissions are possible. The plurality of pixels 103 can further include sub-pixels for emitting light of a white color. For example, each pixel 103 can be composed of a plurality of sub-pixels for emitting different color lights. Each sub-pixel of each of the plurality of pixels 103 can further include a color filter. Each of the plurality of pixels 103 is driven by a thin-film transistor connected to the corresponding gate line 105 and the corresponding data line 107. An area in which the plurality of pixels 103 are formed can be defined as a display area 101.

The data driver 115 generates a gate start pulse and a plurality of clock signals for driving the gate driver 113. In addition, the data driver 115 converts a digital video signal input from the outside (e.g., external device) into an analog video signal using a gamma voltage or the like generated by a gamma voltage generator, and applies the analog video signal to the pixel 103 via the data line 107. The data driver 115 can be bonded to the substrate 111 by an anisotropic conductive film (ACF) applied to a pad formed on the substrate 111. In addition, a flexible printed circuit (FPC), a cable, or the like can be bonded to other plurality of pads for receiving the video signal and the control signal from the outside by the anisotropic conductive film. In addition, an area in which the plurality of pads to which the data driver 115, a flexible printed circuit wiring, and the like can be bonded can be formed and defined as a pad area 102. The anisotropic conductive film can be replaced with a conductive adhesive or a conductive paste, and a type of the conductive adhesive is not limited thereto.

The gate driver 113 is composed of a plurality of shift registers, and each shift register is connected to each gate line 105. The gate driver 113 receives the gate start pulse (GSP) and the plurality of clock signals from the data driver 115, and the shift registers of the gate driver 113 sequentially shift the gate start pulse to activate the plurality of pixels 103 respectively connected to the gate lines 105. In addition, a periphery of the display area 101 including an area in which the gate driver 113 is formed except for the pad area 102 can be defined as a non-display area.

The common voltage line 166 can be formed of a single layer or multiple layers of a metal, which is the same as a metal of the gate line 105 and/or the data line 107, and an insulating layer can be formed on the common voltage line 166. The common voltage line 166 can supply the common voltage to a second electrode of the plurality of pixels 103. As shown in FIG. 4, the common voltage line 166 is formed outwardly of the display area 101 and the gate driver 113 to surround the display area 101 and the gate driver 113.

In particular, when the organic light emitting display apparatus 100 is a top-emission-type organic light emitting display apparatus, because a second electrode of the display area 101 can have a high electrical resistance, the further away from the common voltage line 166, the more the resistance can increase based on the distance. In order to alleviate or address such issue, the common voltage line 166 can be formed to surround the display area 101. However, the present disclosure may not be limited thereto, and the common voltage line 166 can be formed on at least one side of the display area 101.

In order for the second electrode of the plurality of pixels 103 to be electrically connected to the common voltage line 166, the second electrode can be formed on the gate driver 113 to extend to a partial area of the gate driver 113. In addition, the second electrode of the plurality of pixels 103 can be connected to a connection portion made of a material that is the same as a material of a first electrode formed on the gate driver 113. The connection portion made of the material that is the same as the material of the first electrode can be formed on the gate driver 113 and connected to the common voltage line 166 along the gate driver 113. In addition, when an insulating layer exists between the connection portion and the common voltage line 166, the connection portion and the common voltage line 166 can be connected to each other by a contact hole.

The encapsulation portion 140 can be formed to cover the display area 101 and the non-display area. In addition, the encapsulation portion 140 can be formed so as not to cover the pad area 102. For example, because the encapsulation portion 140 can have excellent moisture permeation delay ability as well as excellent electrical insulation ability, the plurality of pads formed in the pad area 102 can be insulated when the encapsulation portion 140 is formed to cover the pad area 102. Therefore, it is preferable that the encapsulation portion 140 is not formed in the pad area 102.

Referring to FIGS. 4 and 5, the organic light emitting display apparatus 100 includes the substrate 111, a thin-film transistor 130 formed on the substrate 111, a light emitting device 120 driven by the thin-film transistor 130, and the encapsulation portion for sealing the light emitting device 120.

The substrate 111 can be made of a film made of a polyimide-based material. In addition, a back-plate for supporting the organic light emitting display apparatus 100 to suppress the organic light emitting display apparatus 100 from shaking too much can be further disposed on a bottom face of the substrate 111.

A multi buffer layer 104 and an active buffer layer 106 are disposed between the substrate 111 and the thin-film transistor 130. The multi buffer layer 104 delays diffusion of moisture and/or oxygen penetrated into the substrate 111. The active buffer layer 106 protects a semiconductor layer 134 and performs a function of blocking various types of defects introduced from the substrate 111.

In this regard, an uppermost layer of the multi buffer layer 104 in contact with the active buffer layer 106 is made of a material having a different etching characteristic from that of the remaining layers other than the multi buffer layer 104, for example, the active buffer layer 106. The uppermost layer of the multi buffer layer 104 in contact with the active buffer layer 106 can be made of one of SiNx and SiOx, and the remaining layers other than the uppermost layer of the multi buffer layer 104, the active buffer layer 106, a gate insulating film 112, and an interlayer insulating film 114 can be made of the other of SiNx and SiOx. For example, the uppermost layer of the multi buffer layer 104 in contact with the active buffer layer 106 is made of SiNx, and the remaining layers other than the uppermost layer of the multi buffer layer 104, the active buffer layer 106, the gate insulating film 112, and the interlayer insulating film 114 can be made of SiOx.

The thin-film transistor T2 (130) includes a gate electrode 132, a semiconductor layer 134 overlapping the gate electrode 132 with the gate insulating film 112 interposed therebetween, and source and drain electrodes 136 and 138 formed on the interlayer insulating film 114 and in contact with the semiconductor layer 134. Herein, the semiconductor layer 134 is formed on the gate insulating film 112 and is made of at least one of an amorphous semiconductor material, a polycrystalline semiconductor material, and an oxide semiconductor material. The thin-film transistor 130 described above is only for helping the understanding of the embodiment. The structure of the thin-film transistor can vary depending on a mask process. A protective film 116 can be disposed on the interlayer insulating film 114.

A first planarization layer 117 can be disposed over the thin-film transistor 130. The first planarization layer 117 has a contact hole defined therein for exposing the drain electrode 138 of the thin-film transistor 130. The first planarization layer 117 functions to make roughness of a surface on which the thin-film transistor 130 is formed uniform. The first planarization layer 117 can be formed in various forms, can be formed of an organic insulating film such as benzocyclobutene (BCB) or acryl or an inorganic insulating film such as a silicon nitride film (SiNx) and a silicon oxide film (SiOx), and can be variously modified, such as being formed in a single layer or in double or multiple layers.

A second planarization layer 118 can be disposed over a pixel connection electrode 139. The second planarization layer 118 can include a contact hole defined therein for exposing the pixel connection electrode 139. The second planarization layer 118 functions to make roughness of a surface of the first planarization layer 117 uniform to apply the light emitting device 120 in a smooth planar state. The second planarization layer 118 can be formed in various forms like the first planarization layer. The second planarization layer 118 can be formed of the organic insulating film such as benzocyclobutene (BCB) or acryl or the inorganic insulating film such as the silicon nitride film (SiNx) and the silicon oxide film (SiOx), and can be variously modified, such as being formed in a single layer or in double or multiple layers.

The pixel connection electrode 139 is disposed between the first and second planarization layers 117 and 118. Such pixel connection electrode 139 is exposed through a first pixel contact hole 137 extending through the protective film 116 and the first planarization layer 117 and is connected to the drain electrode 138. Such pixel connection electrode 139 can be made of a material having a low resistivity in a manner that is the same as or similar to the drain electrode 138.

The light emitting device 120 includes a first electrode 122, at least one light emitting stack 124 formed on the first electrode 122, and a second electrode 126 formed on the light emitting stack 124. The first electrode 122 is electrically connected to the pixel connection electrode 139 exposed through a second pixel contact hole 148 extending through the second planarization layer 118 disposed on the first planarization layer 117. As a result, the first electrode 122 is electrically connected to the drain electrode 138 via the pixel connection electrode 139.

The at least one light emitting stack 124 is formed on the first electrode 122 in a light emitting area defined by a bank 128. The at least one light emitting stack 124 is formed on the first electrode 122 by stacking a hole-related layer, an organic light emitting layer, and an electron-related layer in an order or in a reverse order.

In addition, the light emitting stack 124 can include first and second light emitting stacks facing each other with a charge generation layer (CGL) interposed therebetween. In this case, an organic light emitting layer of one of the first and second light emitting stacks produces blue light, and an organic light emitting layer of the other of the first and second light emitting stacks produces yellow-green light, thereby producing white light through the first and second light emitting stacks. Because the white light generated by the light emitting stack 124 is incident on a color filter positioned above or below the light emitting stack 124, color video can be realized. In addition, the color video can be implemented by generating color light corresponding to each sub-pixel in each light emitting stack 124 without the separate color filter. For example, a light emitting stack 124 of a red (R) sub-pixel can generate red light, a light emitting stack 124 of a green (G) sub-pixel can generate green light, and a light emitting stack 124 of a blue (B) sub-pixel can generate blue light.

The first electrode 122 is formed to correspond to the light emitting area defined on the second planarization layer 118 and is connected to the pixel connection electrode 139 connected to the drain electrode 138 of the thin-film transistor 130 through the second pixel contact hole 148 extending through the second planarization layer 118. The first electrode 122 can be made of a metallic material having a high work function. In this embodiment, the first electrode 122 can be selected as the anode electrode. The first electrode 122 can be made of a reflective material or a reflective plate can be additionally formed beneath the first electrode 122 such that the anode electrode has a reflective property. An analog video signal for displaying the video signal can be applied to the first electrode 122.

The second electrode 126 is formed to face the first electrode 122 with the light emitting stack 124 interposed therebetween and is connected to the common voltage line 166 (see FIG. 4). In this embodiment, the second electrode 126 of the light emitting device 120 can be selected as the cathode electrode. The second electrode 126 can be formed in a single layer or multi-layer structure using a single material such as aluminum (Al), aluminum-neodymium (AlNd), and silver (Ag) having a very small thickness and having a low work function, or formed in a single layer or multi-layer structure using a plurality of materials such as magnesium (Mg), silver (Ag) and aluminum (Al)/silver (Ag). The second electrode 126 can be, for example, formed to have a thickness equal to or lower than 400 Å. When the second electrode 126 is formed to have such a thickness, the second electrode 126 becomes a substantially transflective layer, thereby becoming a substantially transparent layer.

The bank 128 can cover a portion of the first electrode 122 of the light emitting device 120 to define the light emitting area. For example, areas between the banks 128 can be considered the light emitting areas. The bank 128 can be made of an organic material. For example, the bank 128 can be made of polyimide, acryl, or benzocyclobutene-based resin, but may not be limited thereto.

A spacer can be formed on the bank 128. The spacer can be made of an organic film such as an acrylic resin, an epoxy resin, a phenolic resin, a polyamide resin, a polyimide resin, and the like. The spacer can be omitted.

A metal formation inhibiting layer 160 that covers the light emitting area defined by the bank 128 and has an opening defined above the bank 128 can be coated on the second electrode 126. The metal formation inhibiting layer 160 can be deposited using a fine metal mask (FMM). When the fine metal mask is used, a plurality of organic materials of a desired fine pattern can be formed at predetermined positions on the substrate at once. In order to deposit the organic materials of the desired pattern, the FMM can have a plurality of rectangular slots through which the organic materials pass, or can have stripe-shaped slits.

The metal formation inhibiting layer 160 can contain the organic material. For example, a perfluorinated polymer and a fluoropolymer containing polytetrafluoroethylene (PTFE); polyvinyl biphenyl; polyvinylcarbazole (PVK); and polymers formed by polymerizing the plurality of polycyclic aromatic compounds as described above can be contained, but the present disclosure may not be limited thereto.

The metal formation inhibiting layer 160 can be deposited in an area except for a portion where an auxiliary electrode 170, which will be described later, is formed using the FMM. After the metal formation inhibiting layer 160 is formed, a portion of a surface of the second electrode 126 located beneath the metal formation inhibiting layer 160 can be exposed through an opening of the metal formation inhibiting layer 160.

The auxiliary electrode 170 can be formed in the opening of the metal formation inhibiting layer 160 described above. The auxiliary electrode 170 can be made of a metal having a low resistance. For example, the auxiliary electrode 170 can be made of a single material such as aluminum (Al), aluminum-neodymium (AlNd), and silver (Ag), or a plurality of materials such as magnesium (Mg)/silver (Ag) and aluminum (Al)/silver (Ag), but may not be limited thereto.

The auxiliary electrode 170 can be connected to the second electrode 126 through the opening of the metal formation inhibiting layer 160. The auxiliary electrode 170 can be deposited entirely on the metal formation inhibition layer 160 including the opening. Because the metal formation inhibiting layer 160 is able to prevent the auxiliary electrode 170 from being formed, the auxiliary electrode 170 can be selectively formed only in the opening where the metal formation inhibiting layer 160 is not formed. Because of the above-described characteristics of the metal formation inhibiting layer 160, it is possible to reduce process operations compared to the formation of the auxiliary electrode 170 through photolithography and it is possible to reduce unnecessary consumption of a material due to etching. The auxiliary electrode 170 can be in contact with a side face of the metal formation inhibiting layer 160 exposed by the opening in the metal formation inhibiting layer 160.

In case of the top-emission scheme, the light emitted from the organic light emitting layer (e.g., the light emitting stack 124) passes through the second electrode 126. Accordingly, the second electrode 126 can be formed to have a small thickness to allow the light to pass therethrough, so that a resistance of the second electrode 126 increases. For example, when the resistance of the second electrode 126 increases, power consumption usually increases. The cause of the increase in the power consumption can be an increase in IR drop resulted from an increase in a sheet resistance and a voltage drop of a power supply wiring. In order to reduce the resistance of such second electrode 126, the auxiliary electrode 170 can be connected to the second electrode 126 through the opening of the metal formation inhibiting layer 160. The auxiliary electrode 170 can be thicker than the second electrode 126 in order to reduce the resistance of the second electrode 126. For example, the auxiliary electrode 170 can be opaque. Because the position where the auxiliary electrode 170 is formed is the opening of the metal formation inhibiting layer 160 corresponding to the bank 128, the auxiliary electrode 170 may not overlap the light emitting area. Preferably, a width of the auxiliary electrode 170 can be smaller than a width of the bank 128. Because the auxiliary electrode 170 does not optically affect the light emitted from the organic light emitting layer, the auxiliary electrode 170 can be opaque by being formed to have a sufficient thickness to reduce the resistance of the second electrode 126. Further, the auxiliary electrode 170 can be formed to be thicker than the metal formation inhibiting layer 160.

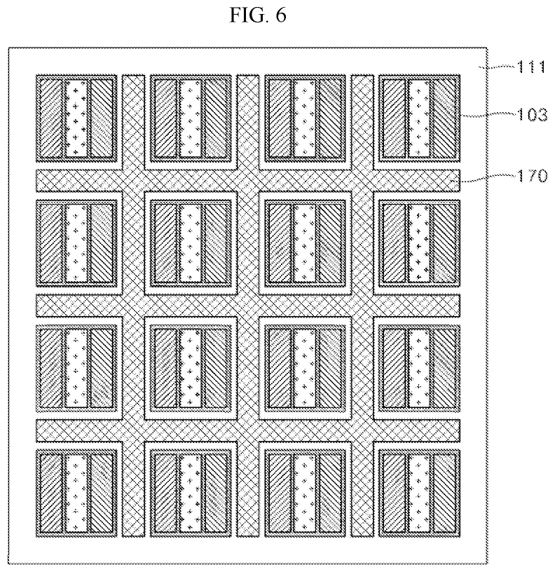

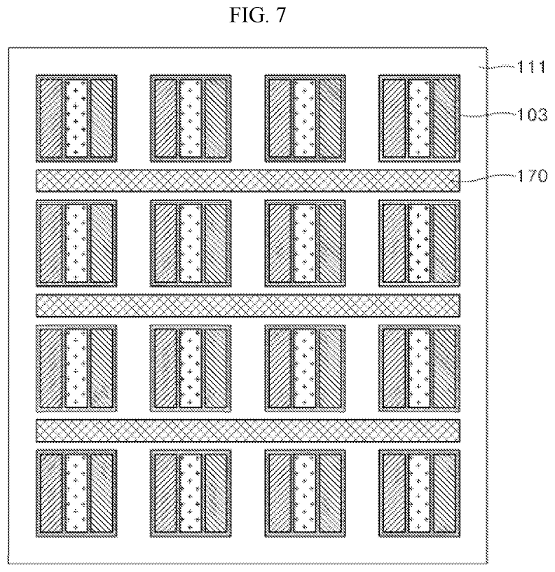

Referring to FIGS. 5 to 7, the auxiliary electrodes 170 can be arranged to intersect each other to be in a mesh or grid structure (e.g., FIG. 6) or can be arranged in one direction to be in a stripe structure (e.g., FIG. 7), but the present disclosure may not be limited thereto. The auxiliary electrodes 170 can surround the pixels 103. The auxiliary electrode 170 can be connected to the common voltage line 166 (see FIG. 4) or the voltage line 150 (see FIG. 4) in the non-display area. In this embodiment, the common voltage line 166 is formed outwardly of the display area 101 (see FIG. 4) to surround the display area 101, but the common voltage line 166 is also able to be formed below the organic light emitting device (e.g., 120) disposed within the display area.

The encapsulation portion 140 can be formed on the auxiliary electrode 170 after the formation of the auxiliary electrode 170. The encapsulation portion 140 blocks the penetration of the external moisture or oxygen into the light emitting device 120, which may be vulnerable to the external moisture or oxygen. To this end, the encapsulation portion 140 can include a plurality of inorganic encapsulation layers and organic encapsulation layers respectively disposed between two of the plurality of inorganic encapsulation layers, and the inorganic encapsulation layer can be disposed at an uppermost layer of the encapsulation portion 140. In this regard, the encapsulation portion 140 can include at least two inorganic encapsulation layers and at least one organic encapsulation layer.

In the present disclosure, a structure of the encapsulation portion 140 in which the organic encapsulation layer is disposed between first and second inorganic encapsulation layers will now be described below as an example.

In one example, the first inorganic encapsulation layer is formed on the substrate 111 on which the second electrode 126 is formed so as to be closest to the light emitting device 120. Such first inorganic encapsulation layer is made of an inorganic insulating material that can be deposited at a low temperature, such as the silicon nitride (SiNx), the silicon oxide (SiOx), a silicon oxynitride (SiON), or an aluminum oxide (Al2O3). Accordingly, because the first inorganic encapsulation layer is deposited in a low-temperature atmosphere, during the deposition process of the first inorganic encapsulation layer, it is possible to prevent damage to the light emitting stack 124, which may be vulnerable to a high temperature atmosphere.

The organic encapsulation layer serves as a buffer to relieve stress between layers based on bending of the organic light emitting display apparatus, and enhances a planarization performance. The organic encapsulation layer can be made of an organic material. For the organic encapsulation layer, silicon oxycarbon (SiOCz) can be used or the acryl or epoxy-based resin can be used, but the present disclosure may not be limited thereto. For example, when the organic encapsulation layer is made of SiOCz, the organic encapsulation layer can be formed by a CVD (chemical vapor deposition) process. Further, SiOCz is the inorganic material, but is able to be classified as the organic material under specific conditions. Specifically, SiOCz has different flow properties depending on a silicon and carbon atomic ratio (C/Si ratio). For example, when the flow properties of SiOCz deteriorate, SiOCz has properties close to the inorganic material, so that a performance of compensating for foreign substances is lowered. When the flow properties thereof are improved, SiOCz has properties close to the organic material, so that the performance of compensating for the foreign substances is improved. The C/Si ratio of SiOCz can be controlled by adjusting a ratio of oxygen (02) and hexamethyldisiloxane (HMDSO) during the CVD process. In particular, when the organic encapsulation layer is made of SiOCz, a thickness of the encapsulation portion 140 can be very small so that the thickness of the organic light emitting display apparatus can be reduced advantageously.

For example, when the organic encapsulation layer is made of the acrylic or epoxy-based resin, the organic encapsulation layer can be formed by a slit coating or a screen printing process. In this regard, as the epoxy-based resin, high-viscosity bisphenol-A-epoxy, low-viscosity bisphenol-F-epoxy, and the like can be used. The organic encapsulation layer can further contain an additive. For example, a wetting agent that reduces a surface tension of the resin for improving uniformity of the resin, a leveling agent for improving surface flatness of the resin, and a defoaming agent for removing air bubbles contained in the resin can be further added as the additive. The organic encapsulation layer can further contain an initiator. For example, it is possible to use an antimony-based initiator or an anhydride-based initiator that hardens a liquid resin by initiating a chain reaction by heat.

In addition, when a temperature of the resin rises, viscosity of the liquid resin can be rapidly lowered. After a certain period of time, curing starts and the viscosity can rise sharply, and then, the curing is completed. However, because the resin has high fluidity during the certain period of time when the viscosity is lowered, a possibility of an occurrence of over-application may be particularly increased during such period of time.

The organic encapsulation layer functions to cover foreign substances or particles that can occur during the process. For example, in the first inorganic encapsulation layer, defects due to cracks generated by the foreign substances or the particles may exist. However, such curves and foreign substances can be covered by the organic encapsulation layer, and a top face of the organic encapsulation layer can be planarized. For example, the organic encapsulation layer compensates for the foreign substances and planarizes the display area. As a result, the organic encapsulation layer can be referred to as a foreign substance compensating layer.

The second inorganic encapsulation layer can be formed to cover a top face and side faces of the organic encapsulation layer and a top face of the first inorganic encapsulation layer exposed by the organic encapsulation layer. Accordingly, the second inorganic encapsulation layer minimizes or blocks the penetration of the external moisture or oxygen into the first inorganic encapsulation layer and the organic encapsulation layer. Such second inorganic encapsulation layer can be made of the inorganic insulating material such as the silicon nitride (SiNx), the silicon oxide (SiOx), the silicon oxynitride (SiON), or the aluminum oxide (Al2O3). The first and second inorganic encapsulation layers can be made of the same material, and each can be of a plurality of layers.

Further, the encapsulation portion 140 can be preferably formed with a total thickness in a range from 10 IA to 30 μm to sufficiently prevent the moisture penetration from the outside and prevent flow of internal particles and influence of internal particles.

As such, as the metal formation inhibiting layer 160 including the opening is formed at the position corresponding to the bank 128 on the second electrode 126 and the auxiliary electrode 170 connected to the second electrode 126 is formed in the opening, it is possible to minimize the rise of the sheet resistance of the second electrode 126 and the voltage drop of the power supply wiring.

Further, it is possible to minimize defect and chamber contamination due to the foreign substances compared to a method for allowing the second electrode 126 and the auxiliary electrode 170 to contact with each other using a laser.

Furthermore, a tact time can be shortened to improve productivity. As a result, it is possible to provide a highly reliable organic light emitting display apparatus according to the embodiments of the present disclosure.

A scope of protection of the present disclosure should be construed by the scope of the claims, and all technical ideas within the scope equivalent thereto should be construed as being included in the scope of the present disclosure. Although the embodiments of the present disclosure have been described in more detail with reference to the accompanying drawings, the present disclosure is not necessarily limited to these embodiments. The present disclosure can be implemented in various modified manners within the scope not departing from the technical idea of the present disclosure. Accordingly, the embodiments disclosed in the present disclosure are not intended to limit the technical idea of the present disclosure, but to describe the present disclosure. The scope of the technical idea of the present disclosure is not limited by the embodiments.

Therefore, it should be understood that the embodiments as described above are illustrative and non-limiting in all respects. The scope of protection of the present disclosure should be interpreted by the claims, and all technical ideas within the scope of the present disclosure should be interpreted as being included in the scope of the present disclosure.

What is claimed is:

1. An organic light emitting display apparatus comprising:
a substrate having a display area and a non-display area adjacent to the display area, the display area including a plurality of pixels;
a thin-film transistor disposed in the display area of the substrate;
a first electrode disposed over the thin-film transistor to be connected to a drain electrode of the thin-film transistor;
a bank disposed over the first electrode and defining a first opening for exposing a portion of the first electrode;
a light emitting stack disposed over the first electrode and in the first opening;
a second electrode disposed over the light emitting stack;
a metal formation inhibiting layer disposed over the second electrode and having a second opening for exposing a portion of the second electrode at a location above the bank; and
an auxiliary electrode disposed above the bank,
wherein the auxiliary electrode is electrically connected to the second electrode.

2. The organic light emitting display apparatus of claim 1, wherein the auxiliary electrode is arranged in one direction to have a stripe structure or is arranged to intersect each other to have a mesh structure.

3. The organic light emitting display apparatus of claim 1, wherein the auxiliary electrode is disposed in the second opening of the metal formation inhibiting layer.

4. The organic light emitting display apparatus of claim 1, wherein the auxiliary electrode is in contact with a side face of the metal formation inhibiting layer exposed by the second opening of the metal formation inhibiting layer.

5. The organic light emitting display apparatus of claim 1, wherein the plurality of pixels include a light-emitting area and a non-light-emitting area, and the bank covers a portion of the first electrode to define the light-emitting area.

6. The organic light emitting display apparatus of claim 5, wherein the auxiliary electrode overlaps the non-light emitting area.

7. The organic light emitting display apparatus of claim 4, wherein a thickness of the auxiliary electrode is greater than a thickness of the metal formation inhibiting layer or a thickness of the second electrode.

8. The organic light emitting display apparatus of claim 1, wherein a width of the auxiliary electrode is smaller than a width of the bank.

9. The organic light emitting display apparatus of claim 1, wherein the auxiliary electrode is made of an opaque metal.

10. The organic light emitting display apparatus of claim 1, wherein the second electrode and the auxiliary electrode are connected to a common voltage line.

11. The organic light emitting display apparatus of claim 1, wherein the metal formation inhibiting layer is deposited using a fine metal mask and extends to cover a light-emitting area of the plurality of pixels.

12. The organic light emitting display apparatus of claim 1, wherein the metal formation inhibiting layer contains an organic material.

13. An organic light emitting display apparatus comprising:
a display area configured to display images;
a thin-film transistor disposed in the display area;
at least one planarization layer disposed over the thin-film transistor and including at least one contact hole;
a light emitting device disposed over the at least one planarization layer, and including a light emitting layer defining a first opening;
a bank disposed in the first opening;
a metal formation inhibiting layer disposed over the light emitting device, and defining a second opening; and
an auxiliary electrode disposed above the bank and in the second opening.

14. The organic light emitting display apparatus of claim 13, further comprising:
a pad area disposed adjacent to the display area; and
an encapsulation layer covering the entire display area, but not the pad area.

15. The organic light emitting display apparatus of claim 13, wherein the light emitting device further includes a first electrode on the at least one planarization layer, and a second electrode on the light emitting layer,
wherein the first electrode is electrically connected to the thin-film transistor through the at least one contact hole, and
wherein the auxiliary electrode contacts the second electrode through the second opening.

16. The organic light emitting display apparatus of claim 15, wherein the second electrode and the auxiliary electrode are connected to a common voltage line disposed in a non-display area adjacent to the display area.

17. The organic light emitting display apparatus of claim 15, wherein a thickness of the auxiliary electrode is greater than at least one of a thickness of the metal formation inhibiting layer and a thickness of the second electrode.

18. The organic light emitting display apparatus of claim 13, wherein the auxiliary electrode has a stripe shape and extends in one direction.

19. The organic light emitting display apparatus of claim 13, wherein the auxiliary electrode has a grid shape and extends in two directions that are perpendicular to each other.

20. The organic light emitting display apparatus of claim 13, wherein the bank is disposed above the at least one contact hole, and the auxiliary electrode is made of an opaque metal.
